(19) United States
(12) Patent Application Publication
(10) Pub. No.: US 2022/0190268 A1
(43) Pub. Date: Jun. 16, 2022

(54) OPTOELECTRONIC DEVICE COMPRISING AN ACTIVE ORGANIC LAYER WITH IMPROVED PERFORMANCE AND METHOD FOR PRODUCING SAID DEVICE

(71) Applicant: ISORG, Limoges CEDEX 3 (FR)

(72) Inventors: François FLAMEIN, GRENOBLE (FR); Emeline SARACCO, GRENOBLE (FR); Benjamin BOUTHINON, GRENOBLE (FR); David GUILLERMARD, GRENOBLE (FR)

(21) Appl. No.: 17/628,070

(22) PCT Filed: Jul. 16, 2020
(86) PCT No.: PCT/EP2020/070118

§ 371 Date: Jan. 18, 2022

(30) Foreign Application Priority Data
Jul. 19, 2019 (FR) 19/08250

(51) Int. Cl. H01L 51/44; H01L 51/00

(52) U.S. Cl. CPC H01L 51/441; H01L 27/307; H01L 51/0034

(57) ABSTRACT

A method of manufacturing an optoelectronic device includes the successive steps of forming on a support first and second electrically-conductive pads; depositing an active organic layer covering the first and second electrically-conductive pads; depositing a first interface layer on the active organic layer in contact with the active organic layer; forming a first opening in the first interface layer and a second opening in the active organic layer in line with the first opening, to expose the second electrically-conductive pad; and forming a second interface layer at least partly extending in the first and second openings. The second interface layer is in contact with the first interface layer and with the second electrically-conductive pad.

The present patent application claims the priority benefit of French patent application FR19/08250, which is herein incorporated by reference.

### FIELD

The present disclosure generally concerns optoelectronic devices comprising optical sensors with organic photodiodes or display pixels with organic light-emitting diodes and methods of manufacturing the same.

### BACKGROUND

The manufacturing of an optoelectronic device generally comprises the successive forming of at least partially overlapping elements, at least one of these elements being made of an organic material. A method of manufacturing an organic element comprises the deposition of an organic layer and the etching of portions of the organic layer to delimit the organic element.

An organic optoelectronic device generally comprises an active organic layer which is the area of the optoelectronic device where most of the radiation of interest is captured by the optoelectronic device or from which most of the radiation of interest is emitted by the optoelectronic device.

A disadvantage is that steps of the optoelectronic device manufacturing method, particularly the active layer etching steps, may cause a deterioration of the active layer and thus a decrease in the performance of the optoelectronic device.

### SUMMARY

An embodiment overcomes all or part of the disadvantages of previously described optoelectronic devices.

An object of an embodiment is to prevent a deterioration of the active layer during the manufacturing of the optoelectronic device.

An object of an embodiment is the manufacturing of an optoelectronic device having an improved performance.

An embodiment provides a method of manufacturing an optoelectronic device, comprising the successive steps of:
a) forming on a support first and second electrically-conductive pads;
b) depositing an active organic layer covering the first and second electrically-conductive pads;
c) depositing a first interface layer on the active organic layer in contact with the active organic layer;
d) forming a first opening in the first interface layer and a second opening in the active organic layer in line with the first opening, to expose the second electrically-conductive pad; and
e) forming a second interface layer at least partly extending in the first and second openings, the second interface layer being in contact with the first interface layer and with the second electrically-conductive pad.

According to an embodiment, the forming of the first opening and/or of the second opening is achieved by reactive ion etching.

According to an embodiment, step d) comprises the application of a mask against the first interface layer, said mask comprising a third opening, the first opening being etching in line with the third opening.

According to an embodiment, step d) comprises the deposition of a resist layer on the first interface layer and the forming of a third opening in the resist layer, the first opening being etched in line with the third opening.

According to an embodiment, the method comprises, between steps a) and b), the forming of a resist block facing the second electrically-conductive pad, said block comprising a top and sides, and, after step c), the stack comprising the active organic layer and the first interface layer particularly covers the top of said block and does not totally cover the sides, the method comprising at step d) the removal of said block.

An embodiment also provides an optoelectronic device comprising:
a support;
first and second electrically-conductive pads on the support;
an active organic layer covering the first and second electrically-conductive pads;
a first interface layer covering the active organic layer, in contact with the active organic layer;
a first opening in the first interface layer and a second opening in the active organic layer in line with the first opening; and
a second interface layer extending at least partly in the first and second openings, the second interface layer being in contact with the first interface layer and with the second electrically-conductive pad.

According to an embodiment, the first interface layer and/or the second interface layer comprise at least one compound selected from the group comprising:
a metal oxide;
a host/molecular dopant system;
a conductive or doped semiconductor polymer;
a carbonate;
a polyelectrolyte; and
a mixture of two or more of these materials.

According to an embodiment, the first interface layer and the second interface layer are made of different materials.

According to an embodiment, the first and second conductive pads comprise at least one compound selected from the group comprising:
a conductive oxide;
a metal or a metallic alloy;
a conductive polymer;
carbon, silver, and/or copper nanowires;
graphene; and
a mixture of at least two of these materials.

According to an embodiment, the active organic layer comprises a P-type semiconductor polymer and an N-type semiconductor material, the P-type semiconductor polymer being poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT- C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT) and the N-type semiconductor material being a fullerene, [6,6]-phenyl-C61-methyl butanoate ([60]PCBM), [6,6]-phenyl-C71-methyl butanoate ([70]PCBM), perylene diimide, zinc oxide, or nanocrystals enabling to form quantum dots.

According to an embodiment, the device is capable of emitting or of capturing an electromagnetic radiation, the active organic layer being the layer of the optoelectronic device where most of the electromagnetic radiation is captured by the by the optoelectronic device or from which most of the electromagnetic radiation is emitted by the optoelectronic device.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of the structure obtained at a step of an example of a method of manufacturing an optoelectronic device comprising an active organic layer;

FIG. 2 illustrates another step of the method;

FIG. 3 illustrates another step of the method;

FIG. 4 illustrates another step of the method;

FIG. 5 shows an image acquired by an optoelectronic device illustrating first defects of the active layer of the optoelectronic device;

FIG. 6 shows an image acquired by an optoelectronic device illustrating second defects of the active layer of the optoelectronic device;

FIG. 7 is a partial simplified cross-section view of the structure obtained at a step of an embodiment of a method of manufacturing a optoelectronic device comprising an active organic layer;

FIG. 8 illustrates another step of the method;

FIG. 9 illustrates another step of the method;

FIG. 10 illustrates another step of the method;

FIG. 11 illustrates another step of the method;

FIG. 12 is a partial simplified cross-section view of the structure obtained at a step of another embodiment of a method of manufacturing an optoelectronic device comprising an active organic layer;

FIG. 13 illustrates another step of the method;

FIG. 14 illustrates another step of the method;

FIG. 15 illustrates another step of the method;

FIG. 16 illustrates another step of the method;

FIG. 17 is a partial simplified top view of an embodiment of an organic photodiode;

FIG. 18 is a partial simplified cross-section view of the structure obtained at a step of another embodiment of a method of manufacturing an optoelectronic device comprising an active organic layer;

FIG. 19 illustrates another step of the method;

FIG. 20 illustrates another step of the method;

FIG. 21 illustrates another step of the method;

FIG. 22 illustrates another step of the method;

FIG. 23 illustrates another step of the method; and

FIG. 24 illustrates another step of the method.

### DESCRIPTION OF THE EMBODIMENTS

Like features have been designated by like references in the various figures. In particular, the structural and/or functional features that are common among the various embodiments may have the same references and may dispose identical structural, dimensional and material properties. For the sake of clarity, only the steps and elements that are useful for an understanding of the embodiments described herein have been illustrated and described in detail. In particular, the circuits for controlling photodiodes and light-emitting diodes are well known by those skilled in the art and are not described in detail.

Further, it is here considered that the terms “insulating” and “conductive” respectively mean “electrically insulating” and “electrically conductive”. Further, unless specified otherwise, “in contact with” means “in mechanical contact with”. Further, the term “radiation of interest” designates the radiation which is desired to be captured or emitted by an optoelectronic device. As an example, the radiation of interest may comprise the visible spectrum and near infrared, that is, wavelengths in the range from 400 nm to 1,700 nm, more particularly from 400 nm to 700 nm for the visible spectrum and from 700 nm to 1,700 nm for near infrared. The transmittance of a layer to a radiation corresponds to the ratio of the intensity of the radiation coming out of the layer to the intensity of the radiation entering the layer, the rays of the incoming radiation being perpendicular to the layer. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., it is referred to the orientation of the drawings or to an optoelectronic device in a normal position of use. Unless specified otherwise, the expressions “around”, “approximately”, “substantially” and “in the order of” signify within 10%, and preferably within 5%.

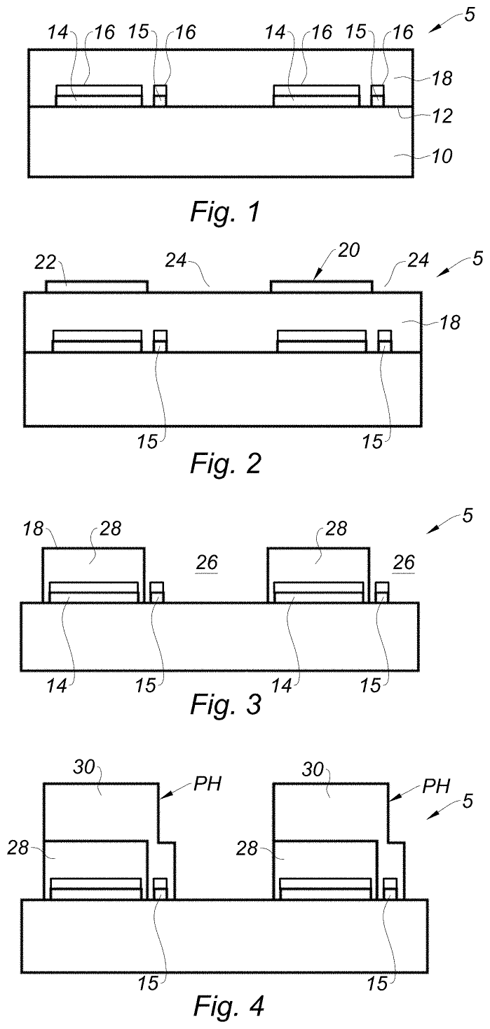

FIGS. 1 to 4 are partial simplified cross-section views of structures obtained a successive steps of a method of manufacturing an optoelectronic device 5 comprising optoelectronic sensors.

FIG. 1 shows the structure obtained after the steps of:
providing a support 10 comprising an upper surface 12;
forming first and second conductive pads 14, 15 on surface 12 of support 10;
forming an interface layer 16 on each conductive pad 14, 15; and
depositing an active organic layer 18 over the entire surface 12 and particularly covering interface layers 16.

FIG. 2 shows the structure obtained after the forming of an etch mask 20 on active layer 18. According to an example, etch mask 20 is a rigid mechanical part which is applied against active layer 18. According to another example, etch mask 20 s obtained by the deposition of a photosensitive resist layer 22 on active layer 18, and the forming of openings 24 in photosensitive layer 22, by photolithography techniques to expose organic layer 18 at the level of second pads 15. According to another example, etch mask 20 is obtained by the deposition of resin blocks directly at the desired locations on active layer 18, for example, by inkjet, heliography, silk-screening, flexography, or nanoimprint. In this case, there is no photolithography step.

FIG. 3 shows the structure obtained after the etching of openings 26 in active layer 18 followed by the removal of etch mask 20. Openings 26 are located in line with openings 24 and expose second pads 15. As illustrated in FIG. 3, openings 26 delimit two active areas 28, each associated with an optoelectronic component, each active area 28 covering one of the first pads 14.

FIG. 4 shows the structure obtained after the forming, for each optoelectronic component, of an interface layer 30 covering active area 28 and second pad 15. Two optoelectronic components PH are thus obtained. According to an example, the film of the material forming interface layers 30 may be deposited over the entire structure shown in FIG. 3 and the delimiting of interface layers 30 may be obtained by etching, by implementing an etch mask that may be formed by steps of photolithography on a resist layer deposited all over the film or by the deposition of resin blocks directly at the desired locations on the film, for example, by inkjet printing, heliography, silk-screening, flexography, or nanoimprint. According to another example, interface layers 30 may be directly deposited at the desired locations, for example, by inkjet printing, heliography, silk-screening, flexography, or nanoimprint.

The performance of the active layer 28 of each optoelectronic component PH particularly depends on the surface condition of active layer 28 in contact with interface layer 30. Generally, it is desirable for the surface of active layer 28 in contact with interface layer 30 to have as few defects as possible, where the defects may correspond to surface asperities, particularly scratches, or to unwanted deposits (particles, contamination, etc.) interposed between active area 28 and interface layer 30. A disadvantage is that the steps of the previously-described manufacturing method may result in the obtaining of active areas 28 exhibiting defects.

In the case where etch mask 20 is a rigid mechanical part applied against active layer 18 during the step of forming of openings 26, the contact of etch mask 20 with active layer 18, particularly during the placing of etch mask 20, may cause the forming of surface defects of active layer 18. Such defects may particularly correspond to scratches capable of extending across the entire thickness of active layer 18. Such defects result in a local decrease in the performance of active layer 18, for example in a higher leakage current or a lower sensitivity.

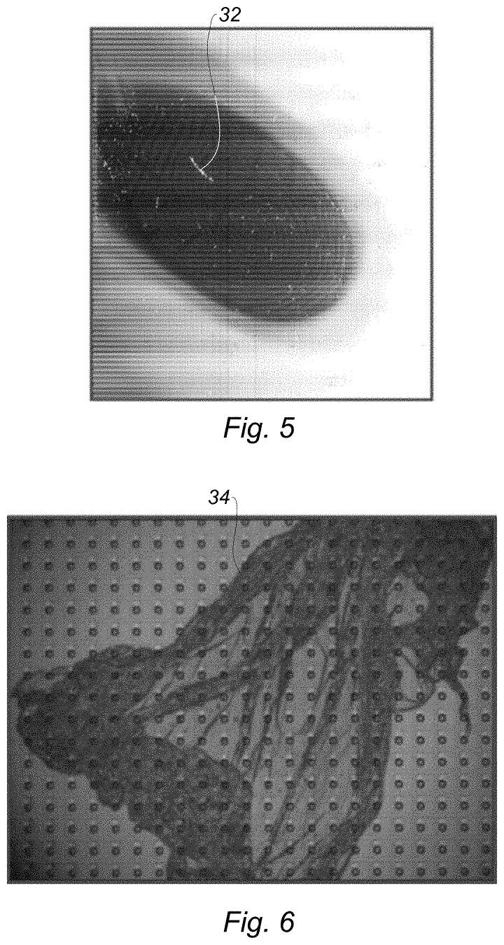

FIG. 5 shows an image obtained in the case where optoelectronic device 5 corresponds to an image sensor used for the acquisition of fingerprints and etch mask 20 is a rigid mechanical part applied against active layer 18. One may observe on the obtained image saturated image pixels 32, corresponding to white image pixels in FIG. 5, due to the surface defects of active layer 18 resulting from the application of etch mask 20, particularly a local short-circuit between interface layer 20 and conductive pad 14 of the photodiode forming the image pixel.

In the case where etch mask 20 is formed from a resin layer 22, a step of removal of etch mask 20 should be carried out after the forming of openings 26 in active layer 18, for example, by dipping of the structure comprising etch mask 20 into a chemical bath. However, the removal of etch mask 20 should not cause an etching in active layer 18, which may introduce constraints relative to the composition of the chemical bath. Thereby, it may be difficult to ensure the total removal of the resin etch mask, which may cause the presence of unwanted residues on active layer 18.

FIG. 6 shows an image obtained in the case where optoelectronic device 5 corresponds to an image sensor and where etch mask 20 is made of resin. The obtained image comprises traces 34 reflecting the presence of residues on active layer 18.

FIGS. 7 to 11 are partial simplified cross-section views of structures obtained at successive steps of an embodiment of a method of manufacturing an optoelectronic device 35.

FIG. 7 shows the structure obtained after the steps of:
providing a support 40 comprising an upper surface 42;
forming, for each optoelectronic component, a first conductive pad or a first conductive track 44 and a second conductive pad or a second conductive track 45 on surface 42 of support 40, two first pads 44 and two second pads 45 being shown in FIG. 7, each optoelectronic component being associated one of first pads 44 and one of second pads 45;
forming an interface layer 46 on each conductive pad 44, 45;
depositing an active organic layer 47 over the entire surface 42 and particularly covering conductive pads 44, 45; and
depositing an interface layer 48 over the entire active layer 47, in contact with active layer 47.

Layers 46, 47, and 48 may each be deposited by liquid deposition. It may in particular be methods such as spin coating, spray coating, heliography, slot-die coating, blade coating, flexography, silk-screening, or dip coating (particularly for layer 46). As a variant, layers 47 and may be deposited by cathode sputtering or by evaporation. According to the implemented deposition method, a step of drying the deposited materials may be provided.

According to an embodiment, support 40 may correspond to an integrated circuit comprising a semiconductor substrate, for example, made of single-crystal silicon, inside and on top of which are formed the insulated-gate field-effect transistors, also called MOS transistors, for example, N-channel and P-channel MOS transistors, and a stack of insulating layers covering the substrate and the transistors, conductive tracks and conductive vias being formed in the stack to electrically couple the transistors and the pads. Integrated circuit 40 may have a thickness in the range from 100 μm to 775 μm, preferably from 200 μm to 400 μm. According to another embodiment, support 40 may be made of a dielectric material. Support 40 is for example a rigid support, particularly made of glass, or a flexible support, for example, made of polymer or of a metallic material. Examples of polymers are polyethylene naphthalene (PEN), polyethylene terephthalate (PET), polyimide (PI), and polyetheretherketone (PEEK). The thickness of support 40 then is, for example, in the range from 20 μm to 1 cm, for example, approximately 125 μm. In the case where the radiation of interest emitted or captured by the optoelectronic components has to cross support 40, the latter may be transparent.

According to an embodiment, the material forming conductive pads 44, 45 is selected from the group comprising:
a conductive oxide such as tungsten oxide (WO₃), nickel oxide (NiO), vanadium oxide (V₂O₅), or molybdenum oxide (MoO₃), particularly a transparent conductive oxide (TCO), particularly indium tin oxide (ITO), an aluminum zinc oxide (AZO), a gallium zinc oxide (GZO), a multilayer ITO/Ag/ITO structure, a multilayer ITO/Mo/ITO structure, a multilayer AZO/Ag/AZO structure, or a multilayer ZnO/Ag/ZnO structure;
titanium nitride (TiN);
a metal or a metallic alloy, for example, silver (Ag), gold (Au), lead (Pb), palladium (Pd), copper (Cu), nickel (Ni), tungsten (W), molybdenum (Mo), aluminum (Al), chromium (Cr), or an alloy of magnesium and silver (MgAg);
a conductive polymer, particularly the PEDOT:PSS polymer, which is a mixture of poly(3,4)-ethylenedioxythiophene and of sodium polystyrene sulfonate, or a polyaniline;
carbon, silver, and/or copper nanowires;
graphene; and
a mixture of at least two of these materials.

In the case where the radiation of interest emitted or captured by the optoelectronic components has to cross support 40, pads 44, 45 may be transparent to the radiation of interest.

Active layer 47 comprises at least one organic material and may comprise a stack or a mixture of a plurality of organic materials. Active layer 47 may comprise a mixture of an electron donor polymer and of an electron acceptor molecule. The thickness of active layer 47 may be in the range from 50 nm to 2 μm, for example, in the order of 300 nm.

Active layer 47 may comprise small molecules, oligomers, or polymers. These may be organic or inorganic materials. Active layer 47 may comprise an ambipolar semiconductor material, or a mixture of an N-type semiconductor material and of a P-type semiconductor material, for example in the form of stacked layers or of an intimate mixture at a nanometer scale to form a volume heterojunction.

Example of P-type semiconductor polymers capable of forming active layer 47 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming active layer 47 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

Interface layer 48 may correspond to an electron injecting layer or to a hole injecting layer. The work function of interface layer 48 is capable of blocking, collecting, or injecting holes and/or electrons according to whether the interface layer plays the role of a cathode or of an anode. More particularly, when interface layer 48 plays the role of an anode, it corresponds to a hole injection and electron blocking layer. The work function of interface layer 48 is then greater than or equal to 4.5 eV, preferably greater than or equal to 4.8 eV. When interface layer 48 plays the role of a cathode, it corresponds to an electron injection and hole blocking layer. The work function of interface layer 48 is then smaller than or equal to 4.5 eV, preferably smaller than or equal to 4.2 eV. In the case where the radiation of interest emitted or captured by active layer 47 has to cross interface layer 48, interface layer 48 is transparent to the radiation of interest. The thickness of oxide layer 48 may be in the range from 10 nm to 2 μm, for example, in the order of 300 nm.

In the case where interface layer 48 plays the role of an electron injection layer, the material forming interface layer 48 is selected from the group comprising:
a metal oxide, particularly a titanium oxide or a zinc oxide;
a host/molecular dopant system, particularly the products commercialized by Novaled under trade names NET-5/NDN-1 or NET-8/MDN-26;
a conductive or doped semiconductor polymer, for example, the PEDOT:Tosylate polymer, which is a mixture of poly(3,4)-ethylenedioxythiophene and of tosylate;
polyethyleneimine (PEI) or a ethoxylated, propoxylated, and/or butoxylated polyethyleneimine (PEIE);
a carbonate, for example CsCO₃;
a polyelectrolyte, for example, poly[9,9-bis(3′-(N,N-dimethylamino)propyl)-2,7-fluorene-alt-2,7-(9,9-dioctyfluorene)] (PFN), poly[3-(6-trimethylammoniumhexyl] thiophene (P3TMAHT) or poly[9,9-bis(2-ethylhexyl)fluorene]-b-poly[3-(6- trimethylammoniumhexyl] thiophene (PF2/6-b-P3TMAHT); and
a mixture of two or more of these materials.

In the case where interface layer 48 plays the role of a hole injecting layer, the material forming interface layer 48 may be selected from the group comprising:
a conductive or doped semiconductor polymer, particularly the materials commercialized under trade names Plexcore OC RG-1100, Plexcore OC RG-1200 by Sigma-Aldrich, the PEDOT:PSS polymer, or a polyaniline;
a molecular host/dopant system, particularly the products commercialized by Novaled under trade names NHT-5/NDP-2 or NHT-18/NDP-9;
tungsten oxide (WO₃);
a polyelectrolyte, for example, Nafion;
a metal oxide, for example, a molybdenum oxide, a vanadium oxide, ITO, or a nickel oxide; and
a mixture of two or more of these materials.

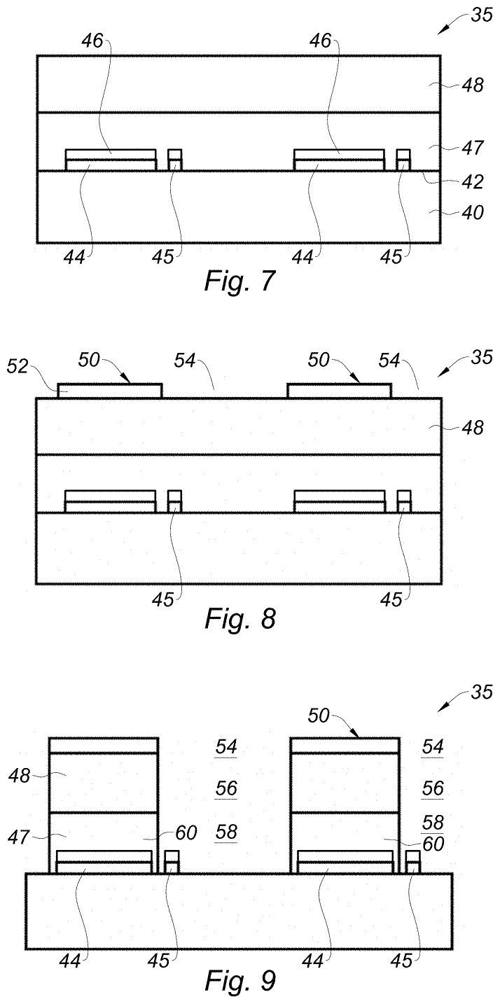

FIG. 8 shows the structure obtained after the forming of an etch mask 50 on interface layer 48. According to an example, etch mask 50 is obtained by the deposition of a resist layer 52 on interface layer 48, and the forming of openings 54 in photosensitive layer 52, by photolithography techniques to expose interface layer 48 particularly at the level of second pads 45. According to another example, etch mask 520 is obtained by the deposition of resin blocks directly at the desired locations on interface layer 48, for example, by inkjet, heliography, silk-screening, flexography, or nanoimprint. In this case, there is no photolithography step. According to another example, etch mask 50 is a rigid mechanical part comprising openings 54 and which is applied against interface layer 48.

FIG. 9 shows the structure obtained after the etching of openings 56 in interface layer 48 in line with openings 54 and the etching of openings 58 in active layer 47 in line with openings 56, particularly to expose second pads 45. In the present example, openings 56, 58 delimit two active layers 60 each associated with an optoelectronic component, each active area 60 covering the first associated pad 44. Each etching may be a reactive ion etching (RIE) or a chemical etching.

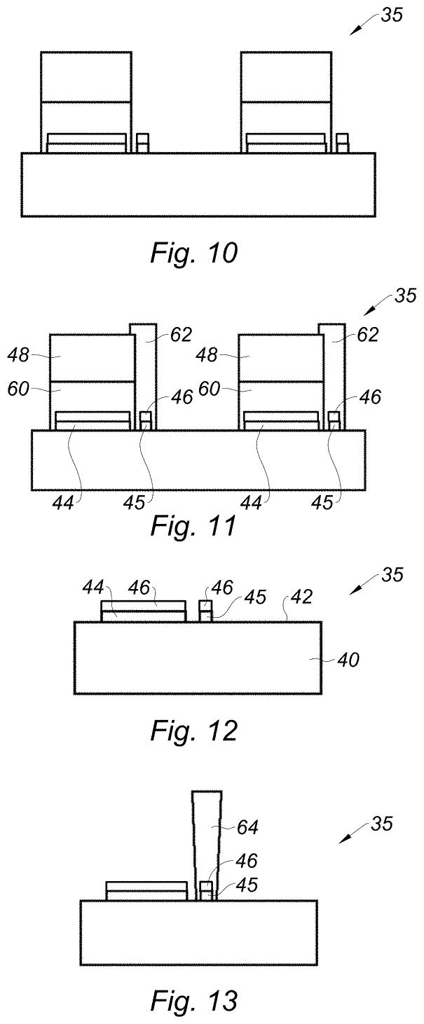

FIG. 10 shows the structure obtained after the removal of etch mask 50. When etch mask 50 is made of resin, the removal of etch mask 50 may be obtained by any stripping method, for example, by dipping the structure comprising etch mask 50 into a chemical bath or by RIE etching.

FIG. 11 shows the structure obtained after the forming, for each active area 60, of a conductive connection element 62 at least partially covering interface layer 48 and covering the associated second pad 45, preferably in contact with interface layer 48, and in contact with interface layer 48 covering second pad 45. Connection element 62 may be made of one of the conductive materials of the list of materials previously mentioned for interface layer 48. Connection element 62 may be made of the same material as interface layer 48 or of a material different from that of interface layer 48. When interface layer 48 is made of a non-conductive material, connection element 62 preferably totally covers interface layer 48. According to an embodiment, interface layer 48 may be transparent to the radiation of interest and connection element 62 may be opaque to the radiation of interest, particularly when interface layer 48 is conductive and connection element 62 only partially covers interface layer 48. The maximum thickness of connection element 62 may be in the range from 10 nm to 2 μm.

According to the material forming pads 44, 45 and connection elements 62, the method of forming connection elements 62 may correspond to a so-called additive process, for example, by direct printing of a fluid or viscous composition comprising the material forming the connection tracks at the desired locations, for example, by inkjet printing, heliography, silk-screening, flexography, spray coating, drop-casting, or nanoimprint. According to the material forming pads 44, 45 and connection elements 62, the method of forming connection elements 62 may correspond to a so-called subtractive method, where the material forming the connection tracks is deposited over the entire structure, and where the unused portions are then removed, for example, by photolithography, laser ablation, or by a lift-off method. According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used. According to the implemented deposition method, a step of drying the deposited materials may be provided.

Advantageously, the step of delimiting active areas 60 implements an etch mask 50 which is applied against interface layer 48 and not against active layer 47.

Thereby, the surface of active layer 47 in contact with interface layer 48 is not degraded by etch mask 50. Further, the removal of etch mask 50 may not result in the presence of residues in contact with the interface between active layer 47 and interface layer 48. Further, when etch mask 50 is made of resist, there are less constraints relative to the choice of the treatment implemented for the removal of etch mask 50 due to the decreased sensitivity of interface layer 48.

FIGS. 12 to 16 are partial simplified cross-section views of structures obtained at successive steps of another embodiment of a method of manufacturing optoelectronic device 35.

FIG. 12 shows the structure obtained after the step of forming of conductive pads 44, 45 on surface 42 of support 40 and of interface layers 46 on conductive pads 44, 45, only one conductive pad 44 and one conductive pad 45 being shown in FIGS. 12 to 16.

FIG. 13 shows the structure obtained after a step of forming a sacrificial block 64 on each second pad 45, a single block 64 being shown in FIG. 13. Each sacrificial block 64 is preferably made of resist. Sacrificial blocks 64 may be formed by photolithography steps. According to an embodiment, as shown in FIG. 13, each sacrificial block 64 may have a flared shape from the pad 45 on which it rests, or a so-called cap-shaped profile, that is, it may have a top of larger dimensions than the base in contact with pad 45. According to an example, such a shape may be particularly obtained by providing, during the photolithography steps, a step of hardening the surface of the photosensitive layer used to form blocks 64, for example, by dipping the resin layer into an aromatic solvent, such as chlorobenzene. According to another example, such a shape may be obtained during the resin layer development step, the resin being selected to have a development rate which varies along the direction perpendicular to the resin layer, the resin layer being more resistant to development on the side of its free upper surface. According to an embodiment, the dimensions of the base of block 64 are greater than those of pad 45 to ensure that block 64 covers the entire pad 45.

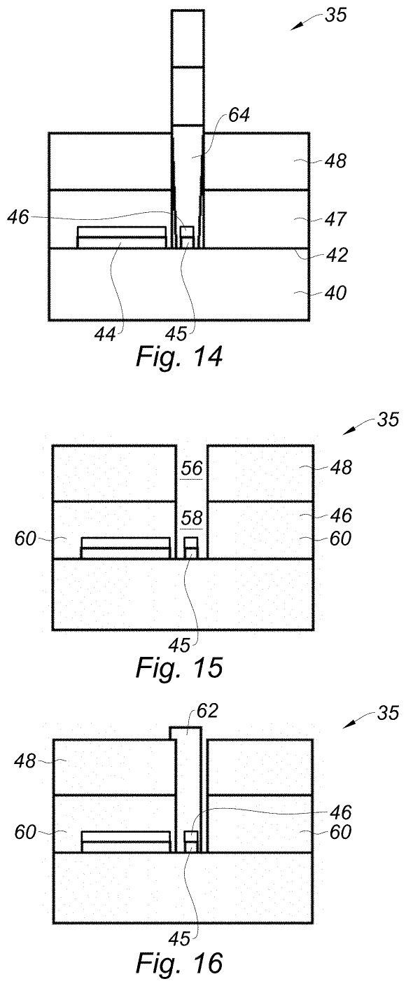

FIG. 14 shows the structure obtained after a step of deposition of active layer 47 and of interface layer 48 over the entire structure shown in FIG. 13. The thickness of the portion of each sacrificial block 64 resting on interface layer 46 is preferably greater than the sum of the thicknesses of active layer 47 and of interface layer 48. The stack of active layer 47 and of interface layer 48 extends on pads 44, 45, on surface 42 of support 40 between pads 44, 45, and on the upper surface of each sacrificial block 64. The stack forming method is preferably a directional deposition method so that, due to the flared shape of block 64, which is wider at its top than at its base, the stack does not deposit on at least part of the lateral walls of block 64.

FIG. 15 shows the structure obtained after a step of removal of sacrificial blocks 64. According to an embodiment, this is achieved by dipping the structure shown in FIG. 14 into a bath containing a solvent which dissolves sacrificial blocks 64 selectively without dissolving interface layer 48. The forming of openings 56 in interface layer 48 and of openings 58 in active layer 47 delimiting active areas 60 is thus obtained.

FIG. 16 shows the structure obtained after the forming, for each active area 60, of connection element 62 partially covering interface layer 48 and covering the second associated pad 45, preferably in contact with interface layer 48 and with the interface layer 46 covering second pad 45.

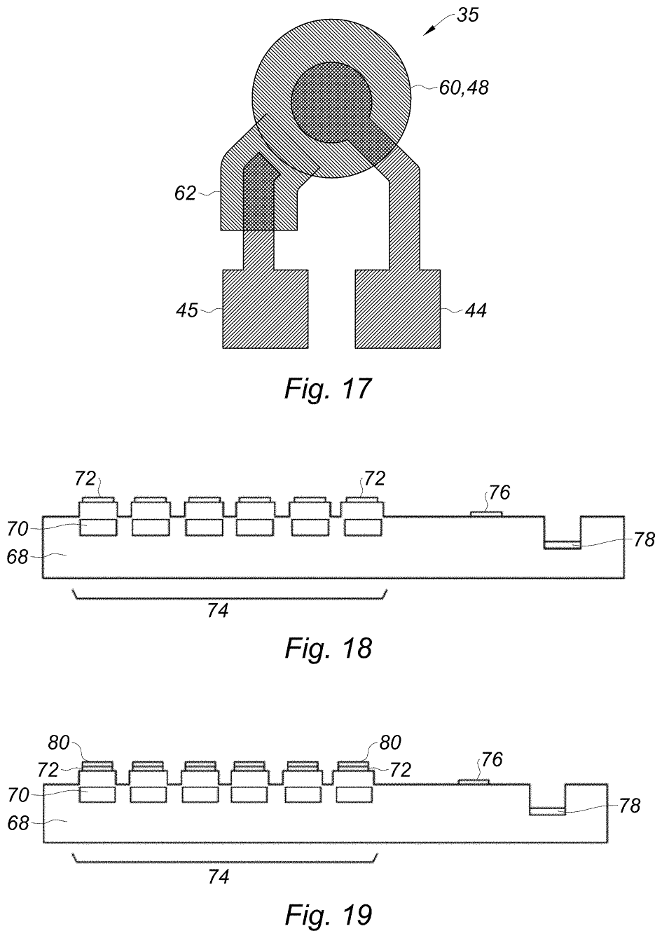

FIG. 17 is a partial simplified top view with transparency of an embodiment of component 35 corresponding to an organic photodiode. In this embodiment, the stack comprising active area 60 and interface layer 48 has a circular shape in top view.

FIGS. 18 to 24 are partial simplified cross-section views of structures obtained at successive steps of an embodiment of a method of manufacturing an optoelectronic device comprising a sensor with organic photodiodes and MOS transistors.

FIG. 18 is a partial simplified cross-section view of an example of an integrated circuit 68 comprising an array of MOS transistors, six readout circuits 70 with MOS transistors being schematically shown by rectangles in FIGS. 18 to 24. According to an embodiment, integrated circuit 68 is formed by techniques conventional in microelectronics. Conductive pads are formed at the surface of integrated circuit 68. Among the conductive pads, pads 72 formed in an area 74 of integrated circuit 68 and which will be used as lower electrodes for organic photodiodes and, outside of area 74, for example, at the periphery of circuit 68, pads 76 which will be used for the biasing of the upper electrode of the photodiodes, a single pad 76 being shown in FIGS. 18 to 24, and pads 78 which will be used for the biasing of integrated circuit 68, a single pad 78 being shown in FIGS. 18 to 24, can be distinguished

Conventionally, integrated circuit 68 may comprise a semiconductor substrate, for example, made of single-crystal silicon, inside and on top of which are formed the insulated gate field-effect transistors, also called MOS transistors, for example, N-channel and P-channel MOS transistors, and a stack of insulating layers covering the substrate and readout circuits 70, conductive tracks and conductive vias being formed in the stack to electrically couple readout circuits 70 and pads 72, 76, 78.

FIG. 19 shows the structure obtained after the forming on each pad 72 of an organic interface layer 80. The forming method used may further cause the forming of the organic layer on pads 76 and 78, which is not shown in

FIG. 19. Interface layer 80 may be made of cesium carbonate (CsCO₃), of metal oxide, particularly of zinc oxide (ZnO), or of a mixture of at least two of these compounds. Interface layer 80 may comprise a self-assembled monomolecular layer or a polymer, for example, (polyethyleneimine, ethoxylated polyethyleneimine, or poly[(9,9-bis(3′-(N,N-dimethylamino)propyl)-2,7-fluorene)-alt-2,7-(9,9-dioctylfluorene)]. The thickness of interface layer 80 is preferably in the range from 0.1 nm to 1 μm. Interface layer 80 may physically graft on pads (and possibly 76 and 78), which directly provides the structure shown in FIG. 19. As a variant, interface layer 80 may be deposited over the entire structure shown in FIG. 18 and then be etched outside of pads 72 to provide the result illustrated in FIG. 19. According to another variant, not illustrated, interface layer 80 may be deposited over the entire structure shown in FIG. 18, this layer having a very low lateral conductivity so that it is not necessary to remove it outside of pads 72, 76, 78.

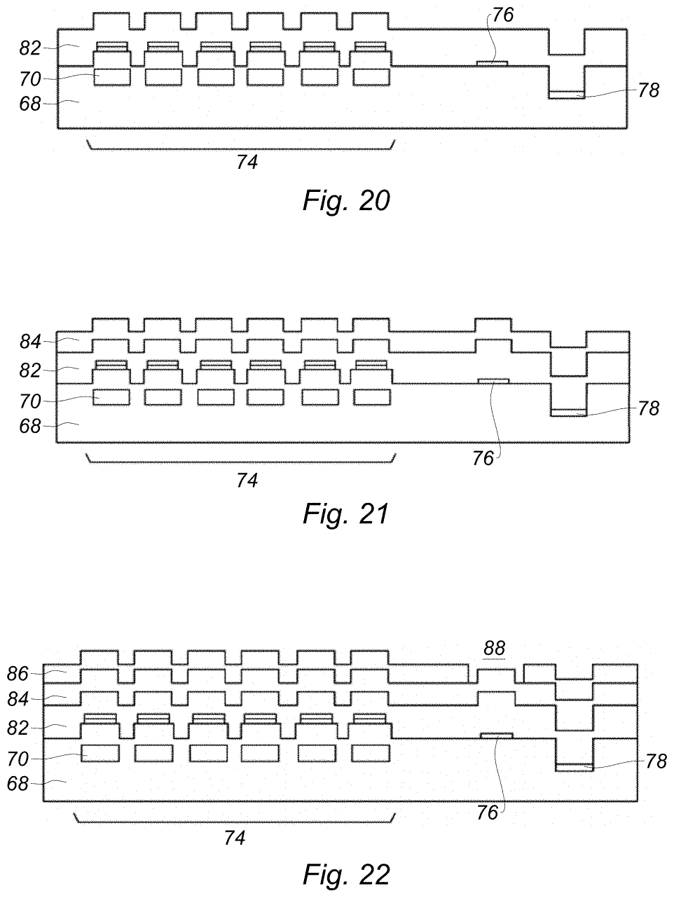

FIG. 20 shows the structure obtained after the forming of an active organic layer 82 over the entire structure shown in FIG. 19 and where, in operation, the active areas of the photodiodes will be formed. Active layer 82 may have the same composition as active layer 47.

FIG. 21 shows the structure obtained after the deposition of an interface layer 84 on active layer 82. Interface layer 84 may have the same composition as interface layer 48.

FIG. 22 shows the structure obtained after the deposition of a resist layer 86 on interface layer 84 and the forming of openings 88 in resist layer 86, by photolithography techniques, a single opening 88 being shown in FIG. 22, to expose interface layer 84 at the level of pads 76.

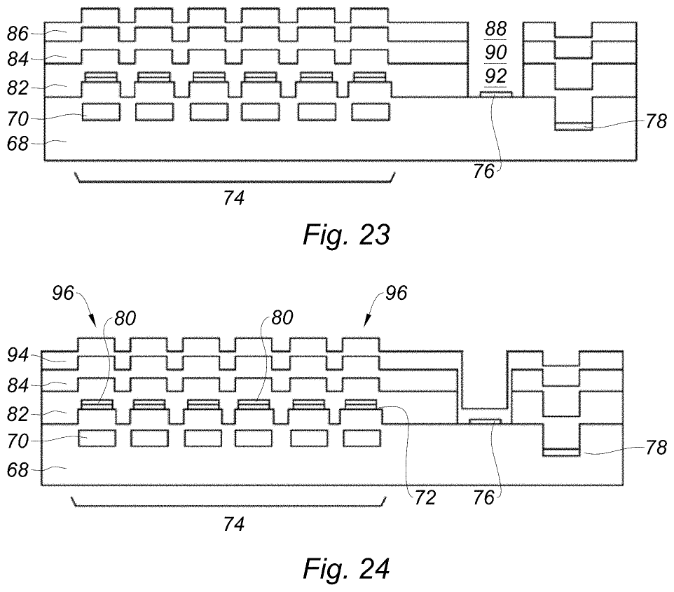

FIG. 23 shows the structure obtained after the etching of openings 90 in interface layer 84 in line with the openings 88 of photosensitive layer 86, and the etching of openings 92 in active layer 82 in line with the openings 90 of interface layer 84 to expose pads 76.

FIG. 24 shows the structure obtained after the removal of photosensitive layer 86 and after the deposition, over the entire structure, of a connection layer 94. Connection layer 94 is particularly in contact with pads 76 and may have the same composition as connection elements 62.

The method may comprise subsequent steps of etching connection layer 94 and the forming of an encapsulation layer covering the entire structure.

The structure comprises, in layer 74, an array of organic photodiodes 96 forming an optical sensor, each photodiode 96 being defined by the portion of organic layers 82, 84 facing one of pads 72. In the example of FIG. 24, six organic photodiodes 96 are shown. In practice, this array is located vertically in line with readout circuits 70 which, in operation, may be used for the control and the reading out of photodiodes 96. In the present embodiment, layer 80 is shown as being discontinuous at the level of photodiodes 96 while organic layers 82 and 84 are shown as being continuous at the level of photodiodes 96. As a variant, interface layer 80 may be continuous at the level of photodiodes 96. The thickness of the stack may be in the range from 300 nm to 1 μm, preferably from 300 nm to 500 nm.

Various embodiments and variants have been described. Those skilled in the art will understand that certain features of these various embodiments and variants may be combined, and other variants will occur to those skilled in the art. Finally, the practical implementation of the described embodiments and variants is within the abilities of those skilled in the art based on the functional indications given hereabove.

1. A method of manufacturing an optoelectronic device, comprising the successive steps of:
a) forming on a support first and second electrically-conductive pads;
b) depositing an active organic layer covering the first and second electrically-conductive pads;
c) depositing a first interface layer on the active organic layer in contact with the active organic layer;
d) forming a first opening in the first interface layer and a second opening in the active organic layer in line with the first opening, to expose the second electrically-conductive pad; and
e) forming a second interface layer extending at least partly in the first and second openings, the second interface layer in contact with the first interface layer and with the second electrically-conductive pad,
wherein the first interface layer and/or the second interface layer comprise at least one compound selected from the group comprising a host/molecular dopant system, a conductive or doped semiconductor polymer, a carbonate, a polyelectrolyte, and a mixture of two or more of these materials.

2. The method according to claim 1, wherein the forming of the first opening and/or of the second opening is achieved by reactive ion etching.

3. The method according to claim 1, wherein step d) further comprises applying a mask against the first interface layer, said mask comprising a third opening, the first opening etched in line with the third opening.

4. The method according to claim 1, wherein step d) further comprises depositing a resist layer on the first interface layer and forming a third opening in the resist layer, the first opening etched in line with the third opening.

5. The method according to claim 1, further comprising, between steps a) and b), forming a resist block facing the second electrically-conductive pad, said block comprising a top and sides, and wherein, after step c), the stack comprising the active organic layer and the first interface layer covers the top of said block and does not totally cover the sides, and at step d) further comprising removing said block.

6. An optoelectronic device comprising:
a support;
first and second electrically-conductive pads on the support;
an active organic layer covering the first and second electrically-conductive pads;
a first interface layer covering the active organic layer, in contact with the active organic layer;
a first opening in the first interface layer and a second opening in the active organic layer in line with the first opening; and
a second interface layer at least partly extending in the first and second openings, the second interface layer being in contact with the first interface layer and with the second electrically-conductive pad,
wherein the first interface layer and/or the second interface layer comprise at least one compound selected from the group comprising a host/molecular dopant system, a conductive or doped semiconductor polymer, a carbonate, a polyelectrolyte, and a mixture of two or more of these materials.

7. (canceled)

8. The optoelectronic device according to claim 6, wherein the first interface layer and the second interface layer are made of different materials.

9. The optoelectronic device according to claim 6, wherein the first and second conductive pads comprise at least one compound selected from the group comprising a conductive oxide, a metal or a metallic alloy, a conductive polymer, carbon, silver, and/or copper nanowires, graphene, and a mixture of at least two of these materials.

10. The optoelectronic device according to claim 6, wherein the active organic layer comprises a P-type semiconductor polymer and an N-type semiconductor material, the P-type semiconductor polymer comprising poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT) and the N-type semiconductor material comprising a fullerene, [6,6]-phenyl-C61-methyl butanoate ([60]PCBM), [6,6]-phenyl-C71-methyl butanoate ([70]PCBM), perylene diimide, zinc oxide, or nanocrystals enabling formation of quantum dots.

11. The optoelectronic device according to claim 6, wherein the optoelectronic device emits or captures an electromagnetic radiation, the active organic layer comprising the layer of the optoelectronic device where most of the electromagnetic radiation is captured by the optoelectronic device or from which most of the electromagnetic radiation is emitted by the optoelectronic device.

12. The method according to claim 1, wherein the first interface layer and/or the second interface layer comprise polyethyleneimine (PEI) or an ethoxylated, propoxylated, and/or butoxylated polyethyleneimine (PEIE).

13. The optoelectronic device according to claim 6, wherein the first interface layer and/or the second interface layer comprise polyethyleneimine (PEI) or an ethoxylated, propoxylated, and/or butoxylated polyethyleneimine (PEIE).
